(19) United States
(12) Patent Application Publication
(10) Pub. No.: US 2002/0058402 A1
(43) Pub. Date: May 16, 2002

(54) Method of forming an etch stop layer during manufacturing of a semiconductor device

(75) Inventors: Karsten Wieczorek, Reichenberg-Boxdorf (DE); Frederick N. Hause, Austin, TX (US); Manfred Horstmann, Dresden (DE)

Correspondence Address: J. Mike Amerson, Williams, Morgan & Amerson, P.C., Suite 250, 7676 Hillmont, Houston, TX, 77040, US

(73) Assignee: Advanced Micro Device, Inc.

(21) Appl. No.: 09/812,347

(22) Filed: Mar. 20, 2001

(30) Foreign Application Priority Data
Nov. 16, 2000 (DE) 100 56 866.1

(51) Int. Cl. H01L 21/3205; H01L 21/4763

(52) U.S. Cl. 438/586

(57) ABSTRACT

In manufacturing a semiconductor device, an etch stop layer is formed on a cobalt silicide layer during a heat treatment when the cobalt and silicon are transformed in a low resistance phase of cobalt silicide. During a predefined time period, oxygen is added to an inert gas ambient and leads to the formation of silicon oxide on the cobalt silicide. Thus, the present invention avoids a deposition step which would otherwise be necessary for forming the silicon oxide layer on top of the cobalt suicide.

### BACKGROUND OF THE INVENTION

1. Field of the Invention

The present invention relates to fabrication of integrated circuit devices and, more particularly, to a method of forming an etch stop layer during manufacturing of a semiconductor device, thereby avoiding unnecessary deposition steps.

2. Description of the Related Art

The manufacturing process of integrating circuits (ICs) involves the fabrication of numerous semiconductor devices, such as resistors, capacitors, or transistors, particularly insulated gate field effect transistors, on a single substrate. In order to increase integration density and improve device performance, for instance with respect to signal processing time and power consumption, feature sizes of the semiconductor devices are steadily decreasing. Therefore, there is a demand for improved, efficient, reliable and inexpensive methods for patterning the structure layers in the integrated circuit suitable to serve the needs for mass production.

Since the market for semiconductor devices is very competitive, semiconductor manufacturers are forced to employ cost-effective processing steps as much as possible while, on the other hand, adhering to the strict design requirements as demanded by modern integrated circuits. It is therefore necessary to keep the required number of processing steps, such as depositing layers of materials on the substrate, as low as possible, since each process step is time-consuming, and additionally increases the risk of contamination which can lead to a reduced reliability or even to a complete failure of the device. Particularly in the manufacturing of very large scale integration (VLSI) devices, which usually have feature sizes of 0.5 μm and beyond, a precise control of both the etching processes in forming local interconnections and of the etch depth is required. To this end, one or more etch stop layers have to be provided in order to precisely define the depth of the etch process.

With reference to FIG. 1, an illustrative method of forming a semiconductor device, in this case a MOS field effect transistor according to a typical prior art process, will be described. It should be noted that for the sake of clarity, the method will merely be schematically described, and those skilled in the art will understand that the method described involves a number of further process steps which are necessary for manufacturing the semi-conductor device, but are not relevant for the teaching of the present invention, and will therefore be omitted.

In FIG. 1, a silicon substrate 101 comprises doped regions 102 acting as a drain and a source, respectively, which are isolated from the surrounding substrate by an isolation 103 which may be provided in the form of shallow trenches. Between the drain and source, a gate electrode 104 substantially consisting of polycrystalline silicon is formed over substrate 101 and is isolated therefrom by a thin gate oxide 105. The sidewalls of the gate electrode 104 are covered by a dielectric material 106, usually referred to as sidewall spacers. The formation of the gate electrode 104, the sidewall spacers 106, and the source and drain regions 102 requires several photolithographical steps, deposition steps, etching steps and implanting steps which are well known to those skilled in the art, and therefore a description thereof will be omitted.

A highly electrically-conductive silicide region 107 is formed on the upper portion of the gate electrode 104 and the drain and source regions 102 so as to minimize the electrical resistance of the gate electrode 104 and the drain and source regions 102, respectively. Typically, the silicide region 107, in this case a cobalt silicide, is formed by depositing a layer of refractory metal (not shown), e.g., cobalt, over the substrate 101, for example, by chemical vapor deposition (CVD), such that a cobalt layer of predefined thickness covers the surface of the drain and source regions 102 and the gate electrode 104. Next, a rapid thermal annealing step is performed with a relatively low temperature so as to initiate a chemical reaction between the silicon in the drain and source regions 102 and the gate electrode 104 and the cobalt layer, resulting in a CoSi compound. After completion of the relatively low temperature thermal annealing step, the excess cobalt (Co) which has not reacted with the silicon is removed and a second rapid thermal annealing step with a relatively high temperature is performed so as to convert the CoSi phase into a highly-conductive metal silicide, e.g., cobalt silicide (CoSi₂), phase.

After the metal silicide (CoSi₂) formation, openings 108 are formed to provide local interconnects which will be filled with a metal for electrical connection to the drain and source regions 102. To this end, usually a dielectric layer in the form of a dielectric stack, including at least two etch stop layers at the bottom of the dielectric stack, is deposited over the substrate 101. Typically the dielectric stack consists of a thick silicon oxide layer 112 which is deposited by low pressure CVD from TEOS. Prior to the deposition of the silicon oxide layer 112, a number of stop layers, in this case two, are deposited to insure a controlled etch stop on both the metal silicide (CoSi₂) and the field oxide. One candidate for a stop layer is silicon nitride, indicated as a first stop layer 111 in FIG. 1, which is generally combined with another thin silicon oxide stop layer, here referred to as second stop layer 110. Second stop layer 110 is required, since silicon nitride may not permanently be put on devices without any buffer layer. As an alternative, the first stop layer 111 and second stop layer 110 may be provided as a combined silicon oxynitride (SiON) layer which, however, has to be deposited by relatively expensive plasma enhanced CVD processing. Moreover, the dielectric stack as proposed above with at least the first stop layer 111 and the second stop layer 110 may be entirely deposited by plasma enhanced CVD processing, but is not desirable in view of production costs and throughput, since the wafers to be processed have to be handled on a single wafer basis. Accordingly, precise formation of local interconnects as required in modern VLSI circuits necessitates the formation of etch stop layers which are conventionally formed by either low pressure CVD batch processing or plasma enhanced CVD single wafer processing.

In view of the above-mentioned problems, there is a need for providing an etch stop layer with a minimum number of cost-intensive processing steps.

### SUMMARY OF THE INVENTION

According to the invention there is provided a method of forming an etch stop layer during manufacturing of a semiconductor device comprising the steps of providing a substrate having a surface in and on which the semiconductor device is to be formed, forming at least one electrically-conductive region in the substrate, the electrically-conductive region comprising silicon, forming a contact portion in at least a portion of the electrically-conductive region, the contact portion comprising a metal and silicon, wherein the metal and the silicon partially form a metal silicon compound, and starting a heat treatment in an inert gas ambient for transforming the metal silicon compound to a low resistance metal silicide phase. The method further comprises adding oxygen to the inert gas ambient during the heat treatment so as to form a silicon oxide layer on the metal silicide, wherein the silicon oxide layer is usable as an etch stop layer for further processing during the manufacture of the semiconductor device.

According to the inventive method, a metal silicide is formed on and in the electrically-conductive region by a heat treatment process so as to provide a contact portion having a lower electrical resistance than the underlying region. Contrary to conventional processing, however, oxygen is added to the inert gas ambient in the reaction chamber in which the heat treatment processing is performed. The oxygen introduced in a controlled manner into the reaction chamber results in the growth of a thin SiO₂ layer on top of the metal silicide. The metal atoms, which will be released by the exchange of oxygen atoms with metal atoms during the reaction, will diffuse deeper into the electrically-conductive region and will further react there to form metal silicide again. The metal silicide layer is therefore “virtually pushed” inside the electrically-conductive region by an amount related to the thickness of the grown SiO₂ layer. This oxide layer may then be used as an etch stop layer in the further processing of the semiconductor device, thereby advantageously eliminating the necessity for either carrying out a relatively expensive SiON plasma enhanced CVD process, or for performing an additional low pressure CVD processing step. In either case, process complexity and, therefore, costs for manufacturing as well as contamination risk are all significantly reduced.

In particular, in high-volume semiconductor manufacturing where critical feature sizes are maintained beyond 1 μm, or even beyond 0.18 μm, precisely-defined etch stop layers such as the SiO₂ layer as described above are required to achieve a high yield while at the same time reducing the number of cost-intensive steps as much as possible.

Preferably, cobalt is used as the metal for forming the silicide on and in the electrically-conductive regions, such as in the drain and source regions and the gate electrode, of a FET transistor, since of the metal suicides currently used in high-volume semiconductor manufacturing, CoSi₂ has the property of forming a SiO₂ layer on the CoSi₂ surface when exposed to an oxidizing ambient during heat treatment processing without suffering any resistance degradation. It may, however, be convenient under certain circumstances to use metals other than cobalt as well for forming the metal silicide and the subsequent silicon oxide layer.

In a further embodiment of the present invention, the oxygen is added during a final phase of said heat treatment, e.g., during the last 5-45 seconds, so as to facilitate control of the final required thickness of the oxide layer.

In a further embodiment, one further etch stop layer, preferably substantially consisting of silicon nitride, is formed on top of the silicon oxide layer so that the further etch stop layer will serve as a stop layer for etching a thick dielectric layer in the course of forming local interconnects in, for example, MIS transistors. Preferably, the silicon nitride layer as well as the thick dielectric layer are deposited by means of cost-effective low pressure CVD.

Further advantages and embodiments of the present invention are defined in the dependent claims.

### BRIEF DESCRIPTION OF THE DRAWINGS

Further advantages and objects of the present invention will become more apparent with the following detailed description when taken with reference to the accompanying drawings in which:

FIG. 1 shows a schematic cross-sectional view of a typical MOS transistor with which a typical prior art processing for forming an etch stop layer is explained;

FIGS. 2a and 2b show schematic cross-sectional views of a semiconductor device, in this case a MOS transistor, in which the processing steps according to the present invention are illustrated; and

FIGS. 2c and 2d schematically show the semiconductor device of FIGS. 2a-2b, wherein further process steps, i.e., formation of a dielectric stack including a further etch stop layer, in accordance with the present invention have been performed.

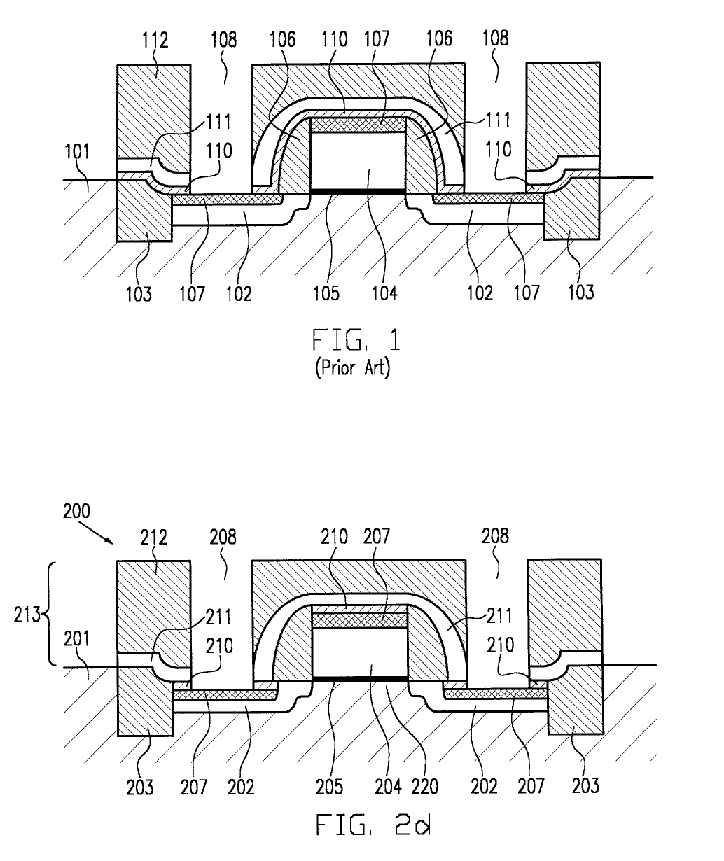

While the present invention is described with reference to the embodiment as illustrated in the following detailed description as well as in the drawings, it should be understood that the following detailed description as well as the drawings are not intended to limit the present invention to the particular embodiment disclosed, but rather the described embodiment merely exemplifies the various aspects of the present invention, the scope of which is defined by the appended claims.

### DETAILED DESCRIPTION OF THE INVENTION

Further advantages and objects of the present invention will become more apparent with the following detailed description and the appended claims. Furthermore, it is to be noted that although the present invention is described with reference to the embodiments as illustrated in the following detailed description, it should be noted that the following detailed description is not intended to limit the present invention to the particular embodiments disclosed, but rather the described embodiment merely exemplifies the various aspects of the present invention, the scope of which is defined by the appended claims.

Moreover, various process steps as described below may be performed differently depending on particular design requirements. Furthermore, in this description only the relevant steps and portions of the device necessary for understanding of the present invention are considered.

It is to be noted that the figures in this application are merely schematic depictions of the various stages in manufacturing the illustrative device under consideration. The skilled person will readily appreciate that the dimensions shown in the figures are not true to scale and that different portions or layers are not separated by sharp boundaries as portrayed in the drawings, but may instead comprise continuous transitions.

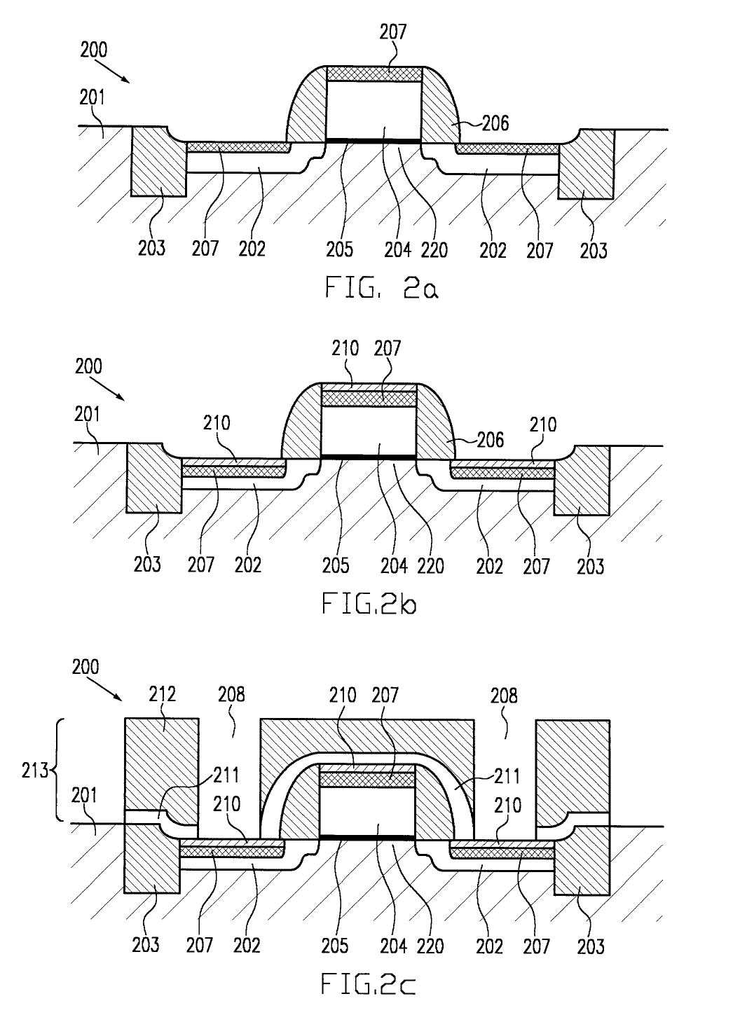

With reference to FIGS. 2a and 2b, an illustrative example of forming an etch stop layer in a semiconductor device in accordance with one embodiment of the present invention will be described. FIG. 2a shows a schematic cross-sectional view of a MOS transistor during its manufacturing process. As shown in FIG. 2a, a transistor 200 is formed in an active area 220 of a silicon substrate 201 that is defined by an isolation 203, which may be provided in the form of shallow trenches as is well known in conventional semiconductor processing. A gate electrode 204 substantially comprised of polycrystalline silicon is formed on a thin gate oxide layer 205 which isolates the gate electrode 204 from the underlying silicon substrate 201. The sidewalls of the gate electrode 204 are covered by sidewall spacers 206 which have been formed after a first implantation step so as to establish electrically-conductive regions 202 which finally serve as a drain and a source 202 in the substrate 201. In one embodiment, the source and drain 202 may be formed in accordance with the following process flow. In a first implantation process, a relatively low concentration of an appropriate dopant material is used. This first implant process is sometimes referred to as an extension implant process in the art. In a second implantation process, a relatively high concentration of the dopant material is implanted after the formation of the sidewall spacers 206. This second implant process is sometimes referred to as a source/drain implant process in the art. Using this process flow, the drain and source 202, respectively, are only lightly doped adjacent the gate electrode 204, due to the shielding effect of the sidewall spacers 206, so as to reduce hot carrier effects. By means of a rapid thermal annealing step, the dopant atoms are activated, i.e., arranged at lattice points of the substrate, as is well-known to the skilled person.

Subsequently, a refractory metal layer (not shown), e.g., cobalt, is deposited over the substrate with a predefined thickness, for example, by CVD. Thereafter, an initial heat treatment process, in this case a low temperature rapid thermal annealing process, is carried out so as to initiate a chemical reaction between the cobalt and the underlying silicon of the drain and source 202 and the gate electrode 204, respectively, so as to generate a high-ohmic cobalt mono silicide (CoSi) layer on top of the drain and source 202 and the gate electrode 204. This initial heat treatment process may be performed at a temperature ranging from approximately 450-600° C. for a duration of approximately 10-60 seconds. Next, excess cobalt which has not reacted with the underlying silicon is removed by a selective etch process. Portions of the drain and source 202 and the gate electrode 204 substantially consisting of the CoSi phase are indicated as contact portions 207. Subsequently, a second heat treatment in the form of a high temperature rapid thermal annealing process in an inert gas ambient, such as a nitrogen (N₂) ambient, is initiated, and the CoSi of the contact portions 207, formed during the first rapid thermal annealing step, is converted into a cobalt silicide (CoSi₂) compound which exhibits a low electrical resistance. In one illustrative embodiment, the second heat treatment is performed at a temperature ranging from approximately 700-1000° C. for a duration of approximately 10-60 seconds.

Contrary to conventional processing, in the method according to the present invention, oxygen is introduced into the nitrogen (N₂) ambient during the second high temperature RTA, which leads to the formation of a silicon dioxide (SiO₂) layer 210 on top of the metal silicide (CoSi₂). The thickness of the silicon oxide layer 210 on top of the silicide layer 207 can be properly controlled by parameters such as oxygen (O₂) concentration, time of presence of oxygen (O₂) in the nitrogen (N₂) ambient, and temperature of the RTA process. Preferably, in this innovative step, the oxygen is introduced into the nitrogen (N₂) ambient towards the end of the thermal cycle rather than providing oxygen from the start of the heat treatment so as to insure that a required thickness of CoSi₂ has already been formed. This results in the formation of a layer of silicon dioxide 210 having a thickness ranging from approximately 10-50% of the thickness of the silicide layer 207.

In one illustrative embodiment, the oxygen may be introduced at a flow rate ranging from approximately 1-100 sccm for a duration of approximately 5-30 seconds. Moreover, the introduction of the oxygen into the RTA chamber may be delayed until some time after the second heat treatment process has begun, e.g., after 30 seconds, or after approximately two/thirds of the second heat treatment process is complete.

It is to be noted that the released cobalt (Co) which results from the reaction of the cobalt silicide (CoSi₂) with the added oxygen diffuses towards the silicide/silicon interface and undergoes a further chemical reaction to again form cobalt silicide (CoSi₂). The cobalt silicide (CoSi₂) layer is therefore “pushed” inside the substrate 201 and the gate electrode 204, respectively, by an amount related to the thickness of the grown silicon oxide layer 210. As previously mentioned, the growth, and therefore the thickness, of the silicon oxide layer 210 is well-controlled and, hence, the final portion of cobalt silicide (CoSi₂) on top of the drain and source 202 and the gate electrode 204, respectively, is also well-defined. The temperature in the final phase of the rapid thermal annealing step when oxygen is added to the inert gas ambient has to be kept at least above 950° C., since cobalt silicide on silicon is stable up to 950° C.

In FIG. 2b, the device of FIG. 2a is shown, wherein the cobalt silicide (CoSi₂) portions 207 are pushed into the drain and source 202 and the gate electrode 204, respectively, according to a thickness of a silicon dioxide layer 210 which has been formed according to the above-described processing steps. It should be noted that any deviation from the stoichiometry of the metal silicide leads to defects such as vacancies or interstitials which may result in an increase in resistivity of the metal silicide layer. Therefore, preferably cobalt is used as the metal in forming the metal silicide on top of an electrically-active region, such as the drain and source 202 or the gate electrode 204, according to the finding of the inventors, as compared to other currently-used metal silicides such as TiSi₂, TaSi₂, WSi₂, etc., cobalt silicide exhibits the property of forming a silicon dioxide (SiO₂) layer 210 on the surface without any substantial degradation in resistivity when exposed to oxidizing ambients. Furthermore, it should be emphasized that the oxide layer 210, which will be used as an etch stop layer for the further processing of the semiconductor device, has been formed without any additional manufacturing step, ie., without any additional CVD step, so that a significant improvement in throughput is achieved.

FIG. 2c schematically shows a further manufacturing stage of the semiconductor device shown in FIGS. 2a and 2b. A dielectric stack 213 has been formed over the substrate, wherein the dielectric stack comprises at least a further etch stop layer 211, in this case formed as a silicon nitride layer, and a thick silicon oxide layer 212 on top of the silicon nitride layer 211. The dielectric stack 213 has been planarized and a photolithographic step has been carried out for a subsequent etch step in order to form openings 208 which will finally act as local interconnects to connect to the drain and source 202. In etching the openings 208, the silicon nitride layer 211 will serve as a stop layer to control the end point of the etch of the thick silicon oxide layer 212. Subsequently, a selective etch step is performed which removes that portion of silicon nitride layer 211 which covers the bottom of openings 208. During this second etch process, the oxide layer 210 on top of the cobalt silicide region 207 serves as an etch stop layer.

FIG. 2d shows the device after the silicon oxide layer 210 at the bottom of the opening 208 has been removed by an etch process with high selectivity to the underlying cobalt silicide. Consequently, in forming the dielectric stack 213 by means of relatively inexpensive LPCVD processing, the method according to the present invention reduces the number of LPCVD steps to achieve the structure depicted in FIG. 2d. More particularly, according to the present invention, the final etch stop layer, i.e., oxide layer 210, is formed during the heat treatment process necessary for forming the cobalt silicide portions 207 which serve as a contact portion 207 of low electrical resistance for the local interconnect to the drain and source 202, and low resistance portion 207 of the gate electrode 204. Moreover, the cost-intensive plasma enhanced CVD processing, in which wafers are processed on a single wafer basis, can be avoided, since it is not necessary to provide a silicon oxynitride (SiON) etch stop layer as the final etch stop layer in the dielectric stack. It should be noted that the present invention is particularly advantageous in the manufacturing of VLSI structures, wherein critical feature sizes are below 1 μm or even below 0.18 μm, since in this case a very precise definition of the etch depth for local interconnects is essential while, on the other hand, the number of required manufacturing steps are kept as low as possible in view of economic constraints. Furthermore, a person skilled in the art will readily appreciate that the present invention may be applied to any other semiconductor device whose manufacturing process requires the formation of contact openings in a dielectric stack comprising a number of etch stop layers for defining a precise depth of the contact openings. Such semiconductor devices may include any type of FET transistors, diode structures, bipolar transistors in combination with FET transistors, etc.

Although the present invention has been described with reference to a silicon substrate, any appropriate substrate, such as glass or other semiconductors, may be used, wherein a silicon layer is provided for establishing an electrically active region.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming an etch stop layer during the manufacturing of a semiconductor device, comprising the steps of:
providing a substrate having a surface in and on which the semiconductor device is to be formed;
forming at least one electrically-conductive region in the substrate, the electrically-conductive region comprising silicon;
forming a contact portion in at least a portion of the electrically-conductive region, the contact portion comprising a metal and silicon, the metal and the silicon partially forming a metal silicon compound;
starting a heat treatment in an inert gas ambient for transforming the metal and the silicon to a low resistance metal silicide phase; and
adding oxygen to the inert gas ambient in the course of the heat treatment so as to form on the metal silicide compound a silicon oxide layer, wherein the silicon oxide layer is usable as an etch stop layer for further processing during the manufacture of the semiconductor device.

2. The method of claim 1 in which said metal is cobalt.

3. The method of claim 1 further comprising depositing a dielectric layer over the substrate by means of low pressure chemical vapor deposition, wherein the dielectric layer comprises as a sub-layer a silicon nitride layer formed on said silicon oxide layer.

4. The method of claim 3, further comprising etching an opening in the dielectric layer at the position of the electrically-conductive region, wherein said sub-layer acts as an etch stop.

5. The method of claim 4, further comprising etching said sub-layer, wherein said silicon oxide layer acts as an etch stop.

6. The method of claim 5, further comprising selectively removing said silicon oxide layers so as to expose the metal silicide.

7. The method of claim 1, wherein said silicon oxide layer is formed to a predefined thickness that is controlled by a parameter of said heat treatment process, said parameter comprises at least one of a time interval of adding the oxygen, a concentration of the oxygen and temperature during the heat treatment.

8. The method of claim 1, wherein said oxygen is added during the last 5-45 seconds of said heat treatment.

9. The method of claim 8, wherein the temperature during the interval when said oxygen is added is higher than 950° C.

10. The method of claim 1, wherein the step of forming a contact region comprises:
depositing a refractory metal on the electrically-conductive region; and
performing a rapid thermal annealing step at a first temperature;
wherein said heat treatment is carried out as a rapid thermal annealing step at a second temperature, the second temperature being higher than the first temperature.

11. The method of claim 1, wherein depositing said dielectric layer is carried out as a batch process so as to process a plurality of said substrates simultaneously.

12. The method of claim 1, wherein said semiconductor device to be manufactured is a MIS transistor device.

13. The method of claim 1, wherein at least one dimension of the electrically-conductive region in a plane parallel to said surface is less than 1 μm.

14. The method of claim 13, wherein at least said one dimension is less than 0.18 μm.
